(19) United States
(12) Patent Application Publication
(10) Pub. No.: US 2007/0227710 A1
(43) Pub. Date: Oct. 4, 2007

(54) Cooling system for electrical devices

(76) Inventors: Christian L. Belady, Richardson, TX (US); Bradley D. Winick, Ft. Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/396,809

(22) Filed: Apr. 3, 2006

(51) Int. Cl. H01L 23/467; F28F 13/12

(52) U.S. Cl. 165/122; 165/121

(57) ABSTRACT

A cooling system for a server includes at least one liquid cooling unit. The liquid cooling unit connects to the server to provide fault-tolerant cooling to the server when a cooling system connected to the server fails.

### BACKGROUND

Densification in data centers is becoming so extreme that the power density of the systems in the center is growing at a rate unmatched by technological developments in data center heating, ventilation, and air-conditioning (HVAC) designs. Current servers and disk storage systems, for example, generate thousands of watts per square meter of footprint. Telecommunication equipment generates two to three times the heat of the servers and disk storage systems.

Computer designers are continuing to invent methods that extend the air-cooling limits of individual racks of computers (or other electronic heat-generating devices) that are air-cooled. High heat capacity racks, however, require extraordinary amounts of air to remove the heat dissipated by the racks and use expensive and large air handling equipment.

Some electrical devices, such as liquid-cooled mainframe computers, do use liquid cooling. In some situations, liquid cooling provides significant improvements over air-cooled systems. For instance, liquid cooling can more effectively remove large amounts of heat from data centers or even single servers.

Prior liquid cooling systems, however, are not fault tolerant. In other words, a server or data center can unexpectedly shutdown if a failure occurs with the cooling system. For example, if the cooling line in a building fails, then a single server or an entire data center will not be sufficiently cooled. As such, the server or entire data center can overheat and shutdown. As another example, if a non-fault tolerant cooling system needs serviced, then all servers or data centers on this cooling system must be temporarily shutdown while the system is repaired.

### BRIEF DESCRIPTION OF THE DRAWINGS

FIG. 1 is an external coolant converter connected to an electronic device in accordance with an exemplary embodiment of the present invention.

FIG. 2 is an electronic device having an internal liquid cooling loop in accordance with an exemplary embodiment of the present invention.

FIG. 3 is an electrical system using both internal and external coolant converters in accordance with an exemplary embodiment of the present invention.

FIG. 4 is an electrical device using redundant internal coolant converters in accordance with an exemplary embodiment of the present invention.

FIG. 5 is a coolant converter in accordance with an exemplary embodiment of the present invention.

FIG. 6 is another example of a coolant converter in accordance with an exemplary embodiment of the present invention.

FIG. 7 is a data center showing various cooling options in accordance with an exemplary embodiment of the present invention.

FIG. 8 is an electrical device using redundant coolant converters with parallel loads in accordance with an exemplary embodiment of the present invention.

FIG. 9 is an electrical device using redundant coolant converters with serial loads in accordance with an exemplary embodiment of the present invention.

FIG. 10 is another example of an electrical device using redundant coolant converters in accordance with an exemplary embodiment of the present invention.

FIG. 11 is an electrical device using redundant coolant converters with air cooled loads in accordance with an exemplary embodiment of the present invention.

FIG. 12 is an electrical device using redundant coolant converters with spray cooled coolant in accordance with an exemplary embodiment of the present invention.

### DETAILED DESCRIPTION

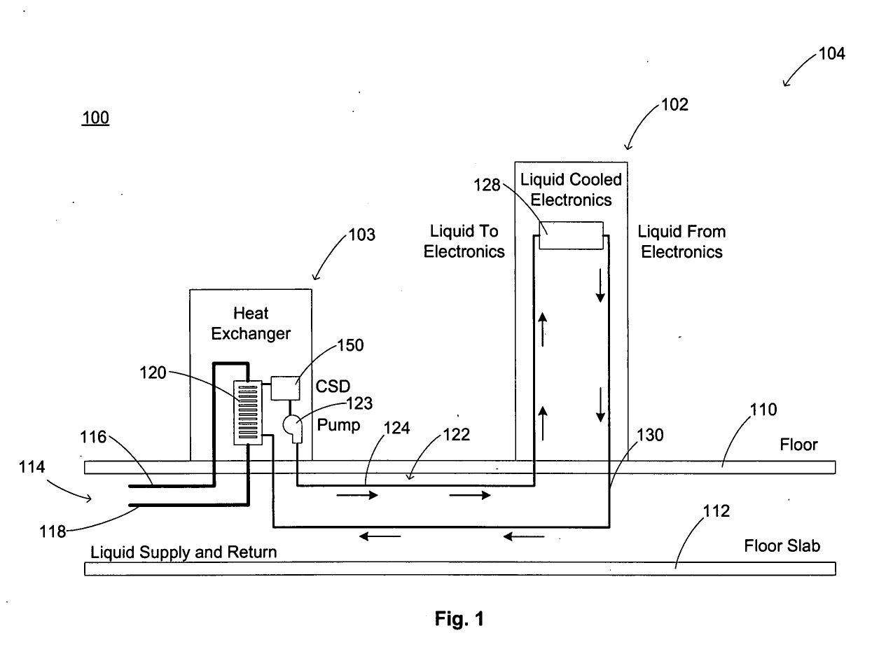

FIG. 1 shows a partial side-view of a cooling system 100 for cooling one or more electronic devices 102. The cooling system includes one or more coolant converters or liquid cooling units 103 for cooling one or more computers (such as computer racks or servers) in a data center 104. For illustration, the data center 104 is shown with an electronic device 102 (example, single server), but multiple servers, computers, and other electronic devices can also be present and cooled with the cooling system.

The data center 104 is situated in a building or room that has a floor 110 above a floor slab 112. A network of pipes 114 extends between the floor 110 and floor slab 112. The pipes carry a cooling fluid to and from the liquid cooling unit 103 and the electronic device 102. By way of example, the cooling fluids include, but are not limited to, water, refrigerant, single phase fluids, two phase fluids, etc. Further, although the pipes are shown within the floor, they can be located in various places, such as, but not limited to, the ceiling, the walls, on top of the floor, underground, etc.

As shown, fluid initially enters the liquid cooling unit 103 along a supply line 116 and exits the liquid cooling unit along a return line 118. Specifically, the fluid passes into a heat exchanger 120, such as a liquid-to-liquid heat exchanger. This heat exchanger 120 is connected to a liquid cooling loop 122 that extends between the liquid cooling unit 103 and the electronic device 102. A pump 123 pumps the fluid along supply line 124 from the heat exchanger 120 to heat generating components or electronics 128. After cooling the electronics 128, the fluid is pumped along return line 130 back to the heat exchanger 120.

The electronics 128 generate heat that is removed by the fluid and transferred away through the return line 130. In turn, the heat exchanger 120 removes, dissipates, and/or exchanges this heat so cooled fluid pumped along the supply line 124 can remove heat from the electronics 128. Embodiments in accordance with the present invention are not limited to any particular type of heat exchanger 128. Various types of heat exchangers, now known or developed in the future, are applicable with embodiments of the invention. By way of example, the heat exchanger 128 can use one or more of thermal dissipation devices, heat pipes, heat spreaders, refrigerants, heat sinks, liquid cold plates or thermal-stiffener plates, evaporators, refrigerators, thermal pads, air flows, and/or other devices adapted to remove or dissipate heat.

In one exemplary embodiment, the cooling system 100 is fault tolerant. For example, if one or more of the supply or return lines 116 or 118 breaks, fails, needs serviced, or otherwise shuts-down, then the electronic device 102 (example, servers or racks in data center 104) will not immediately or contemporaneously overheat and shutdown. In the event of such a failure or servicing in the cooling system 100, the liquid cooling loop 122 extending between the liquid cooling unit 103 and the electronic device 102 continues to cool the electronics 128 for a period of time, for example, until the liquid heats up. During this time, data can be stored to the electronic device or the system can gradually shutdown without overheating. Alternatively, the system can be repaired or serviced before the electronic device is required to shutdown.

One exemplary embodiment uses a coolant storage device 150 located in the liquid cooling unit 103 to provide fault tolerance for cooling system 100. The coolant storage device 150 is a storage tank that stores extra fluid volume (i.e., more than is due, normal, or needed for operations) so the cooling capacity increases for the fluid in the liquid cooling loop 122 and provides additional time for operation during cooling loss to the electronic devices 102 or data center 104. For example, if lines 116 or 118 break or if service is disrupted or disconnected, then the system continues to operate for an extended period of time due to the added fluid capacity in the storage tank. Thus, extra fluid stored in the coolant storage device 150 provides added fluid carrying capacity for servers, racks, and other electronic devices in the date center 104. This extra fluid is used to prolong the runtime of the electronic device 102 so it is not required to be shutdown when, for example, the heat exchanger fails or lines 116 and 118 fail.

Embodiments in accordance with the present invention are not limited to any particular amount of extra fluid stored in the coolant storage device 150. For example, 5%, 10%, 15%, etc. extra fluid can be stored in the coolant storage device 150. On one hand, more extra fluid increases the cooling capacity to the electronics 128 and increases the time period before such electronics overheat or otherwise shutdown. On the other hand, more extra fluid also increases volume and weight to the cooling system 100.

In one exemplary embodiment, the coolant storage device 150 is a porous mass with a high cooling capacity. For instance, this porous mass includes copper or other materials to absorb or dissipate heat. As an example, a copper matrix or other porous medium is placed in a tank or reservoir (example, coolant storage device 150). The porous or added mass provides additional mass so that the cooling capacity increases for the fluid in the liquid cooling loop 122 and provides additional time for operation during cooling loss to the electronic devices 102 or data center 104. Thus, a porous mass in the coolant storage device 150 provides added cooling capacity for servers, racks, and other electronic devices in the date center 104.

Embodiments in accordance with the present invention are not limited to any particular type or amount of porous material in the coolant storage device 150. On one hand, more porous material increases the cooling capacity to the electronics 128 and increases the time period before such electronics overheat or otherwise shutdown. On the other hand, more porous material also increases volume and weight to the cooling system 100.

In yet another exemplary embodiment, the coolant storage device 150 includes a phase change material. Phase change materials exhibit a phase change and utilize energy to change phase. Such materials or compounds melt and/or solidify at certain temperatures in order to store or release energy. As an example, a thermal phase change material (example, ice to water, waxes and paraffin) or phase change matrix or combination is placed in a tank or reservoir (example, coolant storage device 150). The phase change material increases the cooling capacity for the fluid in the internal liquid cooling loop 122 and provides additional time for operation during cooling loss to the electronic devices 102 or data center 104. Thus, a phase change material in the coolant storage device 150 provides added cooling capacity for servers, racks, and other electronic devices in the date center 104.

Embodiments in accordance with the present invention are not limited to any particular type or amount of phase change material in the coolant storage device 150. Different phase change materials offer different degrees of thermal storage and increases in the time period before such electronics overheat or otherwise shutdown. Typically, large amounts of energy are required for phase change; thus, embodiments in accordance with the present invention provide an increases thermal capacity at a higher density.

Thus the coolant storage device 150 provides continued cooling of electronics even after the building coolant discontinues or stops. The cooling system continues to operate as long as the integrity of internal coolant loop is intact and functioning and as long as the stored coolant is not used up.

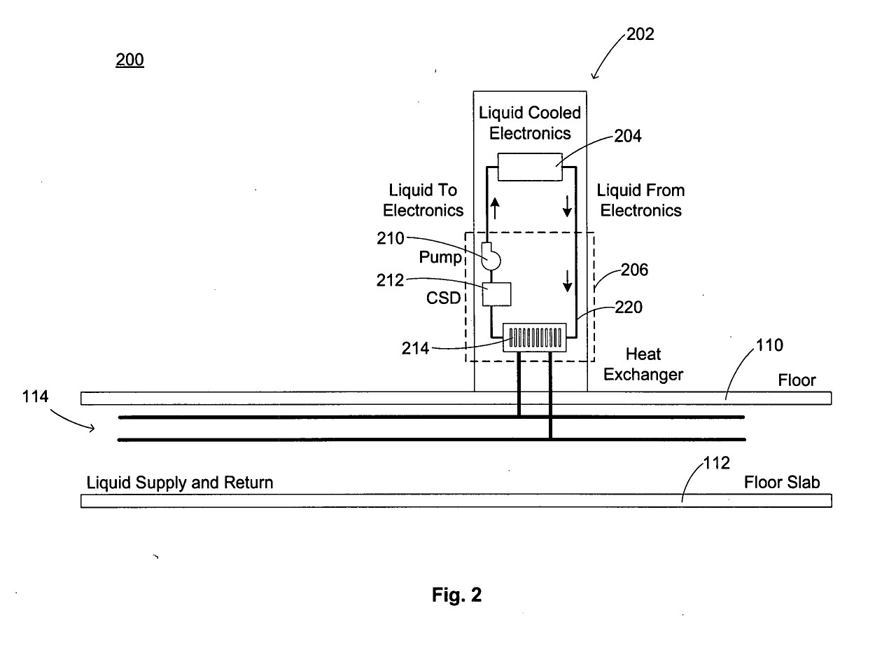

In FIG. 1, the liquid cooling unit 103 is modular and remotely located from the electronic device 102. An internal liquid cooling loop 122 extends between the liquid cooling unit and the electronic device. In alternate embodiments in accordance with the invention, the liquid cooling unit is modular and located within the electronic device(s). In such embodiments, the liquid cooling loop is within the rack, server, or computer. FIG. 2 shows one such exemplary embodiment.

FIG. 2 shows a cooling system 200 having a server or rack 202 with internal electronics 204 and an internal coolant converter unit or liquid cooling unit (shown with dashed lines 206). The liquid cooling unit includes a pump 210, a coolant storage device 212, and a heat exchanger 214. An internal liquid cooling loop 220 extends between the liquid cooled electronics 204 and the heat exchanger 214.

In one exemplary embodiment, the liquid cooling unit 206 is modular and a self-contained unit. For example, the liquid cooling unit is removable, serviceable, and replaceable into the server 202.

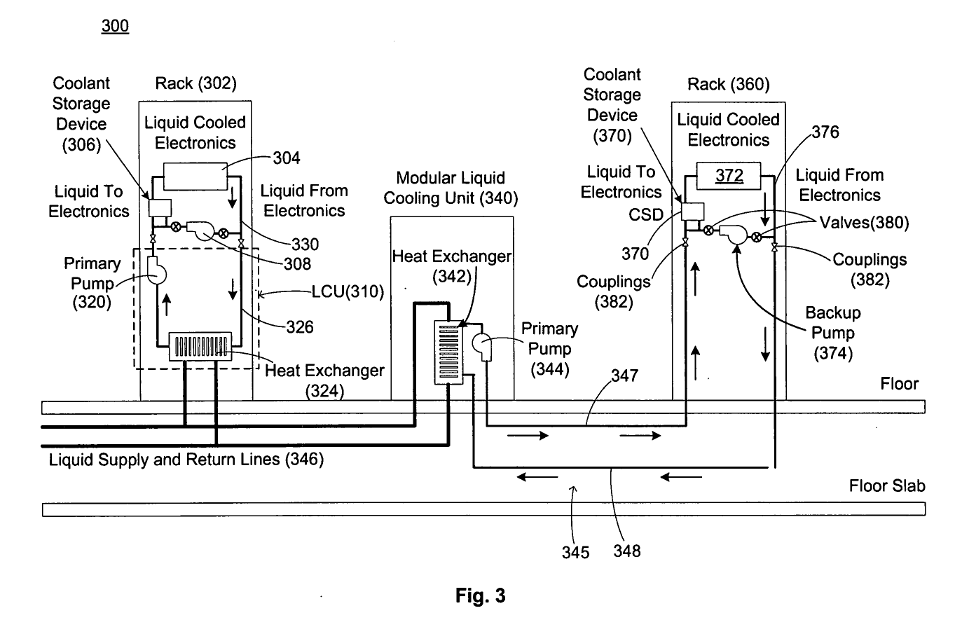

FIG. 3 shows another exemplary embodiment having a cooling system 300 that utilizes both external liquid cooling (as described in connection with FIG. 1) and internal liquid cooling (as described in connection with FIG. 2). As shown, a first rack 302 includes internal electronics 304, a coolant storage device 306, a first pump 308, and a liquid cooling unit (LCU) 310. The liquid cooling unit includes a second or primary pump 320 and a heat exchanger 324. An internal liquid cooling loop 326 provides a fluid pathway between the internal cooling system and electronics in the rack 302.

As shown in FIG. 3, the coolant storage device 306 is integral with the first rack 302. The pump 308 pumps fluid through a secondary-liquid cooling loop 330 that includes the coolant storage device 306 and electronics 304.

As noted, the liquid cooling unit can be modular. As such, the rack 302 can continue to operate while the liquid cooling unit 310 is serviced, replaced, or otherwise repaired. For example, if the primary pump 320 or heat exchanger 324 is temporary shutdown or otherwise fails, the electronics 304 are continued to be cooled within the secondary-liquid cooling loop 330 that extends through the electronics 304, pump 308, and coolant storage device 306. The pump 308 pumps fluid through the electronics within the secondary-liquid cooling loop. The coolant storage device 306 provides the extra coolant, phase change material, or mass needed coolant or fluid necessary to continuously cool the electronics 304 while the liquid cooling unit 310 is serviced, for example.

A modular liquid cooling unit 340 includes a heat exchanger 342 and a primary pump 344. As shown, the liquid supply and return lines 346 connect to both the rack 302 and liquid cooling unit 340. A liquid cooling loop 345 includes a supply line 347 and a return line 348 that circulate fluid to a second rack 360.

The rack 360 includes a coolant storage device 370, liquid cooled electronics 372, and a backup pump 374 all connected via a secondary-liquid cooling loop 376. Plural valves 380 and couplings 382 are used to isolate fluid flow to the electronics 372 along the secondary-liquid cooling loop 376.

In one exemplary embodiment, the primary pump 344 pumps fluid to cool the electronics 372 during normal operations. When servicing or repair is required, dripless couplings 382 are disconnected. Valves 380 are opened and backup pump 374 is activated. Coolant or fluid is circulated through the secondary-liquid cooling loop 376. In turn, the electronics 372 are cooled with the coolant storage device until the stored coolant is used-up. The coolant can store the temperature using, for example, volume of fluid, mass, and/or phase change material as discussed in connection with FIG. 1.

As shown in FIG. 3, even after the building coolant is lost or the internal pump 344 or heat exchanger 342 fails, the cooling system can continue to operate as long as the backup pump 374 and valves 380 properly function. As such, the liquid cooling loop 345 can be serviced or repaired without shutting down the electronics 372 in the rack 360 as long as the stored capacity in the coolant storage device 370 is available for cooling. The coolant storage device thus provides sufficient time for service to return.

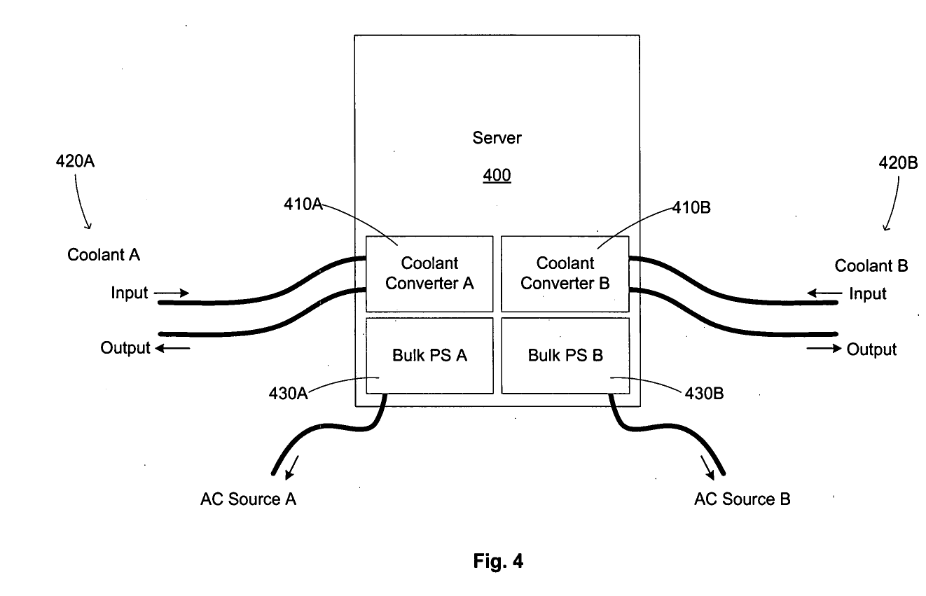

Exemplary embodiments in accordance with the present invention provide various redundant cooling schemes for computers and computer systems (such as data centers). Some embodiments provide a redundant infrastructure that uses a building's liquid or fluid (i.e., coolant) to the computers or computer systems. FIGS. 4-12 provide various additional exemplary embodiments.

FIG. 4 shows electronics or a server 400 having multiple internal and modular redundant liquid cooling units or coolant converters 410A and 410B. The server uses two independent input coolant lines for cooling. Input and output coolant lines 420A are connected to coolant converter 410A, and input and output coolant lines 420B are connected to coolant converter 410B. The coolant converters receive source or building coolant (such as water, refrigerant, air, compressed air, coolanol or any other generally accepted coolant know in the art) and convert it to the desired coolant (such as water, refrigerant, air, compressed air, coolanol or any other generally accepted coolant know in the art) for internal use to the computer or computer system. For example, each coolant converter forms part of a separate and independent cooling loop. These coolant converters 410A and 410B perform several functions. First, they isolate critical internal electrical parts or components of the server from unconditioned building coolant. Second, they allow the server manufacturer to select an optimum cooling media internal to their equipment while using building coolant or other coolant supplies. Third, they control internal coolant temperatures, flow rates, and quality of the fluid that touches or cools the internal electrical parts or components of the server.

The coolant converters 410A and 410B can utilize a redundant power supply, such as a dual grid power system coupled to the server 400. As shown, the server uses two independent power supplies, a bulk power supply A (430A) and bulk power supply B (430B). Specifically, power supply 430A couples to coolant converter 410A, and power supply 430B couples to coolant converter 410B. Each power supply has an independent power source, shown as alternating current AC source A for power supply 430A and AC source B for power supply 430B. The electronics and pumps of coolant converter 410A are powered from power supply 430A, while the electronics and pumps of coolant converter 410B are powered from power supply 430B.

Thus, the server 400 has both redundant power supplies and redundant cooling systems. In one exemplary embodiment, the coolant converters 410A and 410B are identical. In another exemplary embodiment, the coolant converters are different (example, one is a primary coolant converter and one is a backup coolant converter). Further, one coolant converter is a liquid converter and one coolant converter is or utilizes air cooling. Further, since coolants A and B are independent and input separately, these coolants can be the same (example, both water or both refrigerants) or different.

FIG. 4 shows the coolant converters 410A and 410B located above their respective power supplies 430A and 430B. In alternative embodiments, the coolant converters are at the bottom of the server, and the power supplies are above the coolant converters. In this alternate embodiment, liquid connections are below the electronics during an accidental leak. Also, the coolant converters can be combined into a single unit or kept separate so they can be individually serviced and replaced. With this dual and redundant cooling and powering system, the server continues to run while one of the coolant converters fails or otherwise is shutdown.

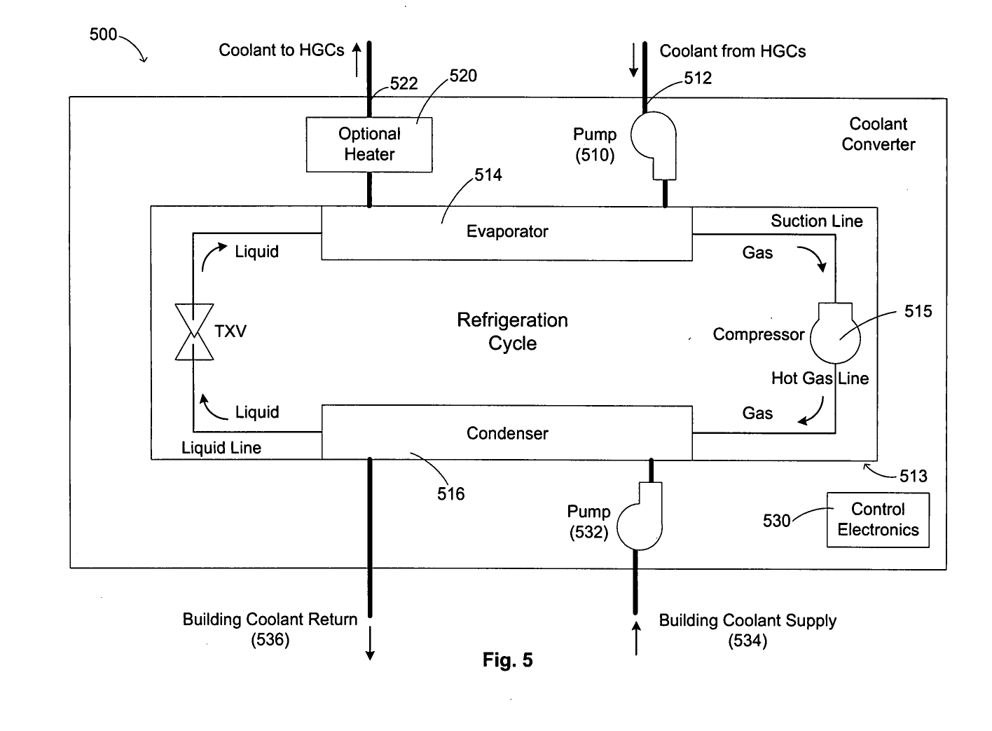

FIG. 5 shows an exemplary coolant converter 500 having a refrigeration cycle. With this embodiment, temperatures are accurately controlled, and supply coolant temperatures can be below ambient temperatures, for example, ambient temperatures in a room or building. Further, the refrigeration cycle can heat or cool the electronics.

As shown, coolant from heat generating components (HGCs, such as computers, computer systems, data centers, etc.) is pumped with pump 510 along line 512. The coolant enters unit 513 at an evaporator 514 and circulates through a compressor 515 and a condenser 516. An optional heater 520 is provided along line 522 as the coolant is returned to the heat generating components. Control electronics 530 control power to the coolant converter 500. These electronics detect failures and monitor and control temperatures and flow rates. Data (such as current readings, measurements, status reports, etc.) are viewable on a display or sent (such as a report) to a server manageability system. Further, as shown, an optional pump 532 is provided to pump coolant along a building coolant supply line 534 and building coolant return line 536.

In an alternate embodiment, the coolant converter 500 includes a heat exchanger (shown in place of unit 513). In this alternate embodiment, if supply temperatures are below the desired internal temperatures, the temperatures can still be accurately controlled. Further in some embodiments, a heat exchanger is more efficient than a refrigeration system. Modulating the supply flow rate is an effective way to control server coolant temperatures as well. As before, the optional heater(s) provide additional control if necessary, and the pumps are located on both inlet and outlet sides.

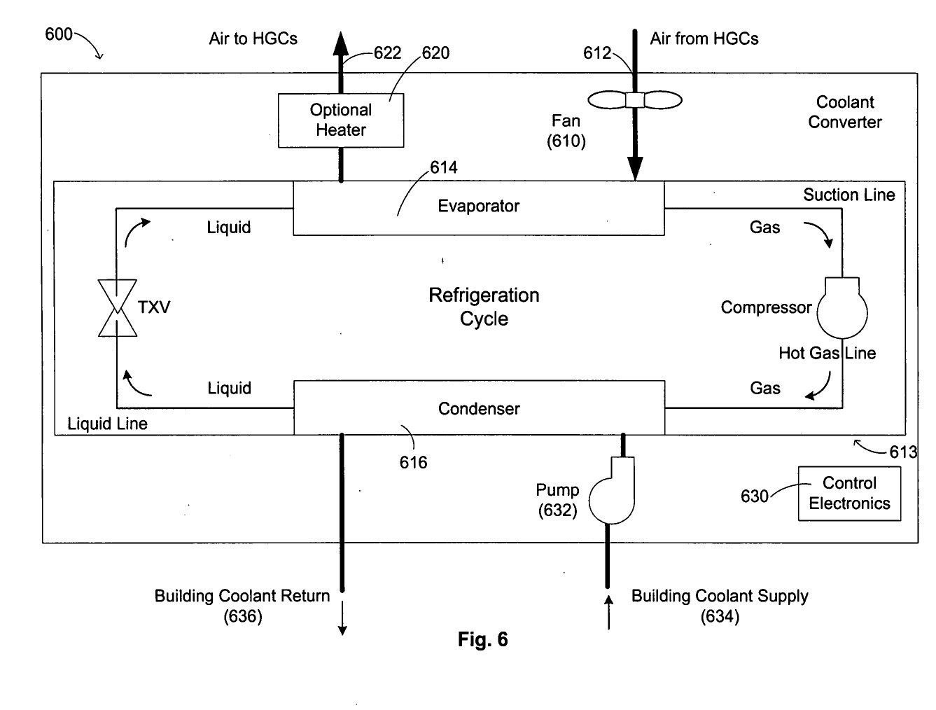

FIG. 6 shows another exemplary coolant converter 600 having a refrigeration cycle wherein air is used as the coolant. With this embodiment, temperatures are accurately controlled, and supply coolant temperatures can be below ambient temperatures, for example, ambient temperatures in a room or building. Further, the refrigeration cycle can heat or cool the room.

As shown, air from heat generating components (HGCs, such as computers, computer systems, data centers) is drawn with a fan 610 along flow path 612. The air enters unit 613 at an evaporator 614 and circulates through a compressor 615 and a condenser 616. An optional heater 620 is provided along flow path 622 as the cooled air is returned to the heat generating components. Control electronics 630 control power to the coolant converter 600. These electronics detect failures and monitor and control temperatures and flow rates. Data (such as current readings, measurements, status reports, etc.) are viewable on a display or sent (such as a report) to a server manageability system. Further, as shown, an optional pump 632 is provided to pump coolant along a building coolant supply line 634 and building coolant return line 636.

In an alternate embodiment, the coolant converter 600 includes a heat exchanger (shown in place of unit 613). In this alternate embodiment, if supply temperatures are below the desired ambient temperatures, the internal temperatures can still be accurately controlled. Further in some embodiments, a heat exchanger is more efficient than a refrigeration system. Modulating the supply flow rate is an effective way to control server temperatures as well. As before, the optional heater(s) provide additional control if necessary, and the pumps are located on both inlet and outlet sides.

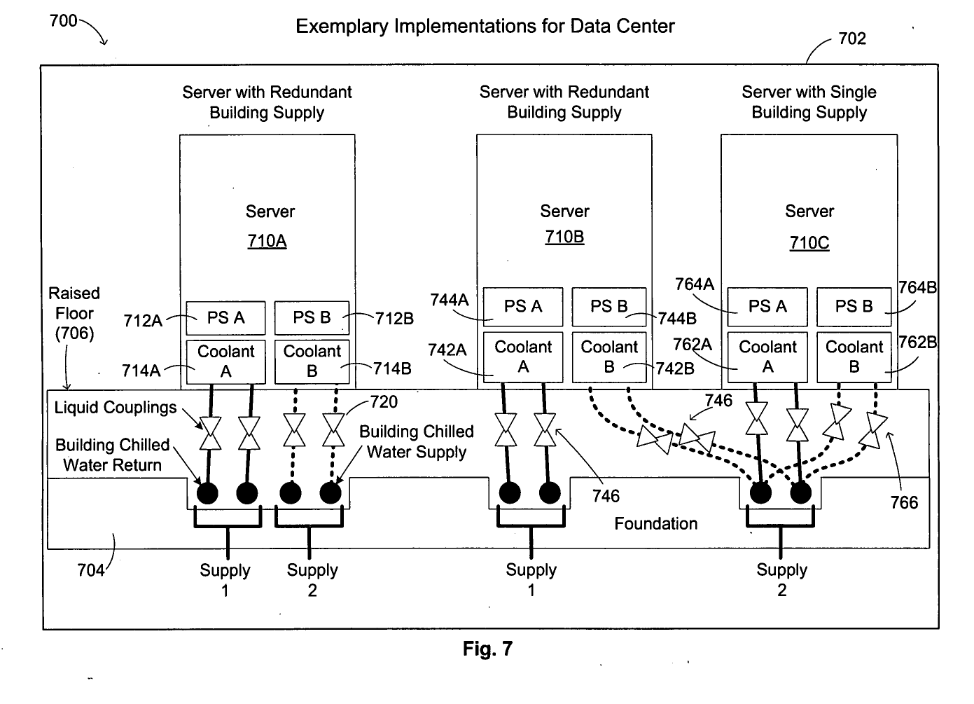

Embodiments in accordance with the invention are connectable to a building coolant system in a variety of ways. FIG. 7 illustrates three exemplary options for connecting servers in a data center to a building coolant system.

FIG. 7 shows a data center 700 disposed in a building 702 having a foundation 704 and floors 706. Three servers are shown to illustrate each of the three options. A first option shows a server 710A connected to have a redundant building coolant supply. The server 710A includes at least two coolant converters 714A and 714B and two power supplies 712A and 712B (such as described in connection with FIG. 4). As shown, a plurality of liquid couplings 720 couple two different coolant supply systems (supply 1 and supply 2) to a base of the server. Each of the supply systems has a supply line and a return line going to a respective coolant converter 714A and 714B. The cooling system of option 1 is redundant and can tolerate both power and coolant failures to the data center 700 and can tolerate failures within the coolant converters themselves.

A second option shows a server 710B connected to have a redundant building coolant supply. The server 710B includes two coolant converters 742A and 742B and two power supplies 744A and 744B (such as described in connection with FIG. 4). As shown, a plurality of liquid couplings 746 couple two different coolant supply systems (supply 1 and supply 2) to a base of the server. Each of the supply systems has a supply line and a return line going to a respective coolant converter 742A and 742B. Specifically, supply line 1 connects to the building coolant system, while supply line 2 couples to another server 710C. The cooling system of option 2 is redundant and can tolerate both power and coolant failures to the data center 700 and can tolerate failures within the coolant converters themselves.

A third option shows a server 710C connected to have a redundant building coolant supply. The server 710C includes two coolant converters 762A and 762B and two power supplies 764A and 764B (such as described in connection with FIG. 4). As shown, a plurality of liquid couplings 766 couple to a coolant supply system, shown as supply 2. A plurality of supply lines and return lines connect to respective coolant converters 762A and 762B. Specifically, supply line 2 connects to the building coolant system and both coolant converters in server 710C. The cooling system of option 3 can tolerate maintenance, service shutdowns, or failures with the coolant converters 762A and 762B, but cannot tolerate a data center level failure.

Embodiments in accordance with the present invention include many different topologies for providing computers, computer systems, and data centers with redundant coolant, such as coolant provided from the building. One such embodiment uses two coolant loops to chill cold plates for heat generating components in an electronic device (example, a server). These cold plates may be a single cold plate with two isolated cooling loops in the assembly. As an alternative, the cold plate may be two separate cold plates that are in intimate contact with each other or the heat generating component.

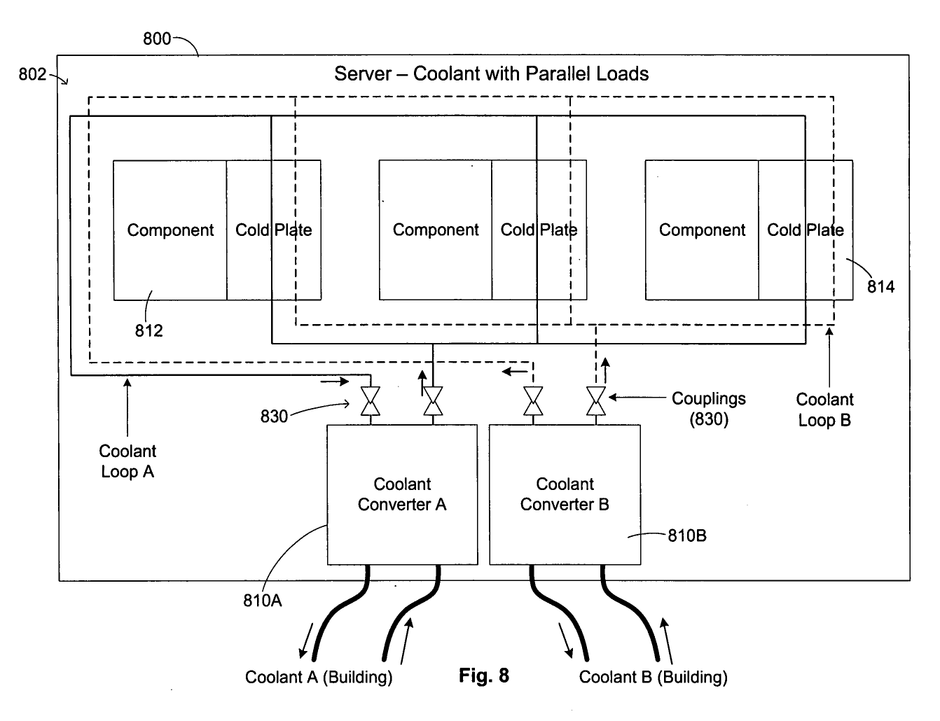

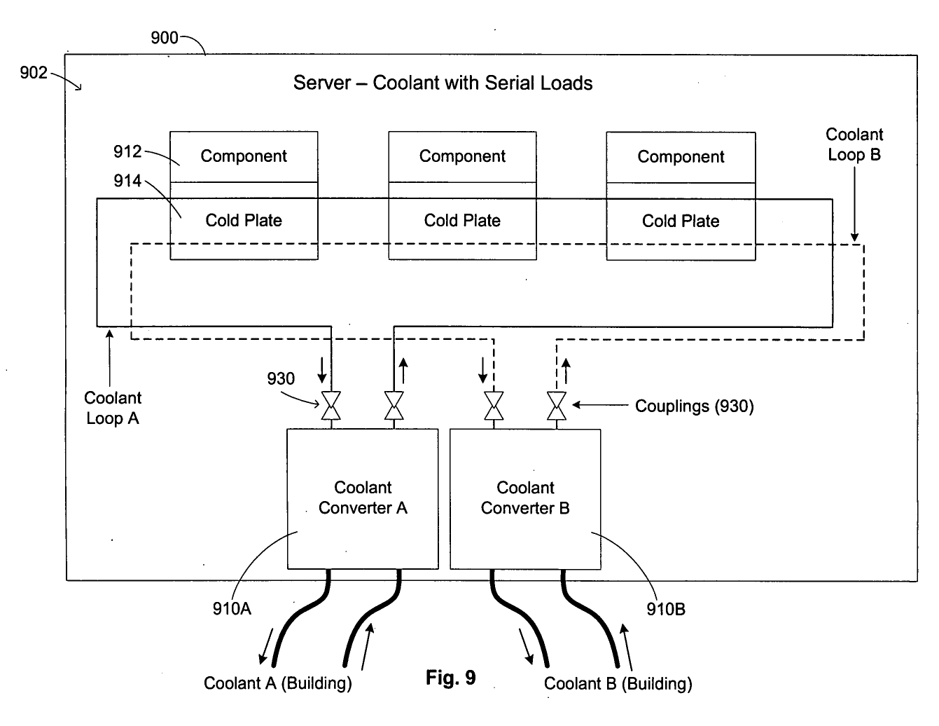

Further, embodiments in accordance with the present invention are connectable to a building or coolant system in a variety of ways that are not limited to the three options discussed in connection with FIG. 7. Such additional options can provide independent servicing of the cooling systems and electronic components. FIGS. 8 and 9 show two exemplar embodiments (one embodiment directed to parallel loads and another embodiment directed to serial loads). If a coolant converter fails, the other coolant converter continues cooling the system in full operation. In addition, the failed coolant converter can be replaced while the system maintains uninterrupted and normal operation. In one exemplary embodiment, leakless couplings are used to provide quick disconnects for servicing components.

FIG. 8 shows a rack or server 800 having an internal coolant system 802 that supplies coolant with parallel loads. Two independent and separate coolant converters 810A and 810B connect to independent and separate coolant supply and return lines (shown as coolant A and coolant B). A plurality of heat generating components 812 and cold plates 814 are cooled with the internal coolant system 802. This coolant system actually has two separate coolant loops (shown as coolant loop A and coolant loop B). As shown, coolant converter 810A feeds or supplies coolant along coolant loop A, and coolant converter 810B feeds or supplies coolant along coolant loop B. Each loop services the loads (i.e., heat generating components and cold plates) in a parallel fashion or network. A plurality of couplings 830 are used to regulate operation between the two coolant loops.

FIG. 9 shows a rack or server 900 having an internal coolant system 902 that supplies coolant with serial loads. Two independent and separate coolant converters 910A and 910B connect to independent and separate coolant supply and return lines (shown as coolant A and coolant B). A plurality of heat generating components 912 and cold plates 914 are cooled with the internal coolant system 902. This coolant system actually has two separate coolant loops (shown as coolant loop A and coolant loop B). As shown, coolant converter 910A feeds or supplies coolant along coolant loop A, and coolant converter 910B feeds or supplies coolant along coolant loop B. Each loop services the loads (i.e., heat generating components and cold plates) in a serial fashion or network. A plurality of couplings 930 are used to connect and disconnect operation between the two coolant loops.

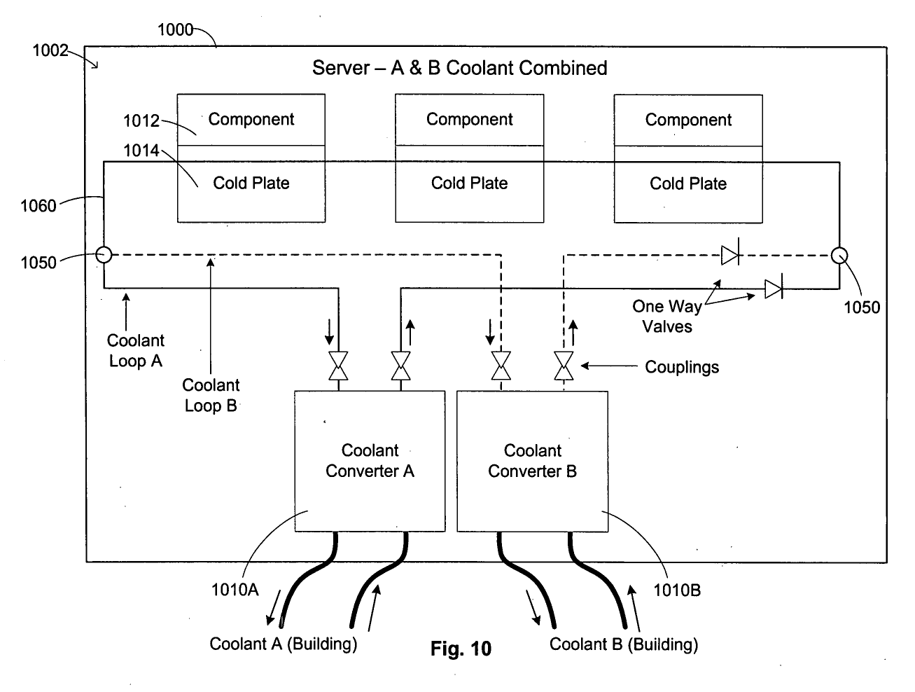

FIG. 10 shows an additional embodiment for providing redundant cooling systems to electronic devices. This embodiment combines the server outlets to coolant converters A and B so that only one set of distribution lines are needed in the system. This embodiment saves on cost and space but does have a single point of failure. One way valves are utilized to ensure that the flow does not reverse and short circuit during a failure of a coolant converter or when one is off.

FIG. 10 shows a rack or server 1000 having an internal coolant system 1002 with combined internal cooling loops. Two independent and separate coolant converters 1010A and 1010B connect to independent and separate coolant supply and return lines (shown as coolant A and coolant B). A plurality of heat generating components 1012 and cold plates 1014 are cooled with the internal coolant system 1002. This coolant system actually has two separate coolant loops (shown as coolant loop A and coolant loop B). As shown, coolant converter 1010A feeds or supplies coolant along coolant loop A, and coolant converter 1010B feeds or supplies coolant along coolant loop B. Each loop services the loads (i.e., heat generating components and cold plates). As shown, the two coolant loops meet or connect at junctions 1050 to share a common line or entry 1060 through the loads. Couplings are provided to connect and disconnect between the various cooling loops.

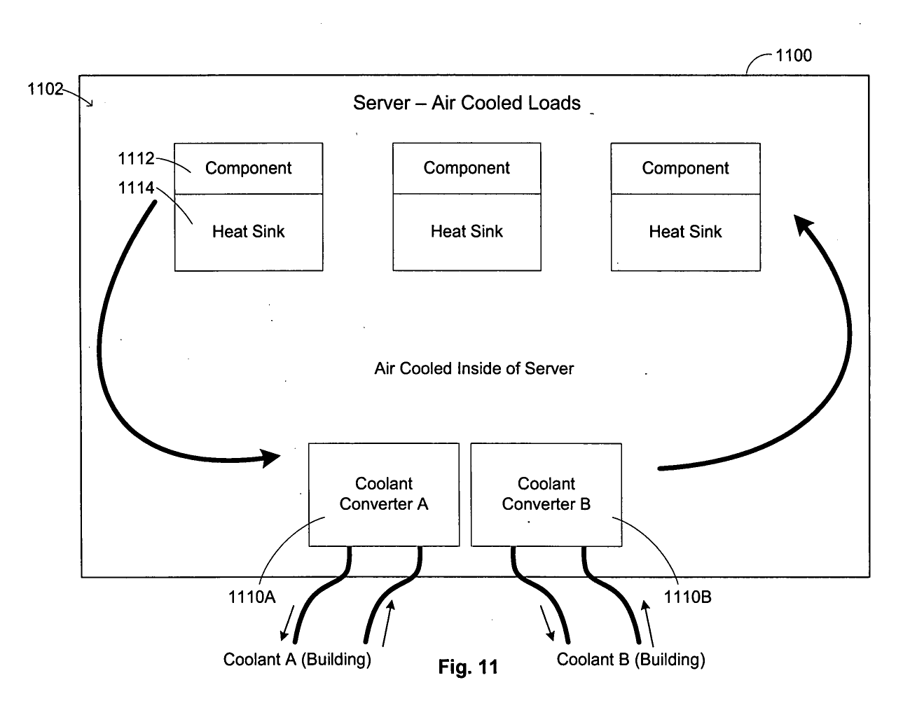

FIG. 11 shows yet another embodiment for providing redundant cooling systems to electronic devices. This embodiment uses two coolant converters to provide conditioned airflow to the server. In this embodiment, the air passes through both the coolant converters in a serial fashion (though alternate embodiments can utilize parallel or other air distribution schemes). If one coolant converter fails, internal air is still circulated and cooled by the remaining coolant converter to chill the air for heat generating components in a server that may or may not have a heat sink or equivalent device. This embodiment allows independent servicing of the server components.

FIG. 11 shows a rack or server 1100 having an internal air-based coolant system 1102. Two independent and separate coolant converters 1110A and 1110B connect to independent and separate coolant supply and return lines (shown as coolant A and coolant B). A plurality of heat generating components 1112 and heat sinks 1114 are cooled with the internal air-based coolant system 1102. This coolant system actually uses one or more airflows to circulate through the server and remove heat from the heat sinks 1114 and to the coolant converters 1100A and 1100B. As shown, coolant converter 1110A feeds or supplies coolant along coolant loop A, and coolant converter 1110B feeds or supplies coolant along coolant loop B.

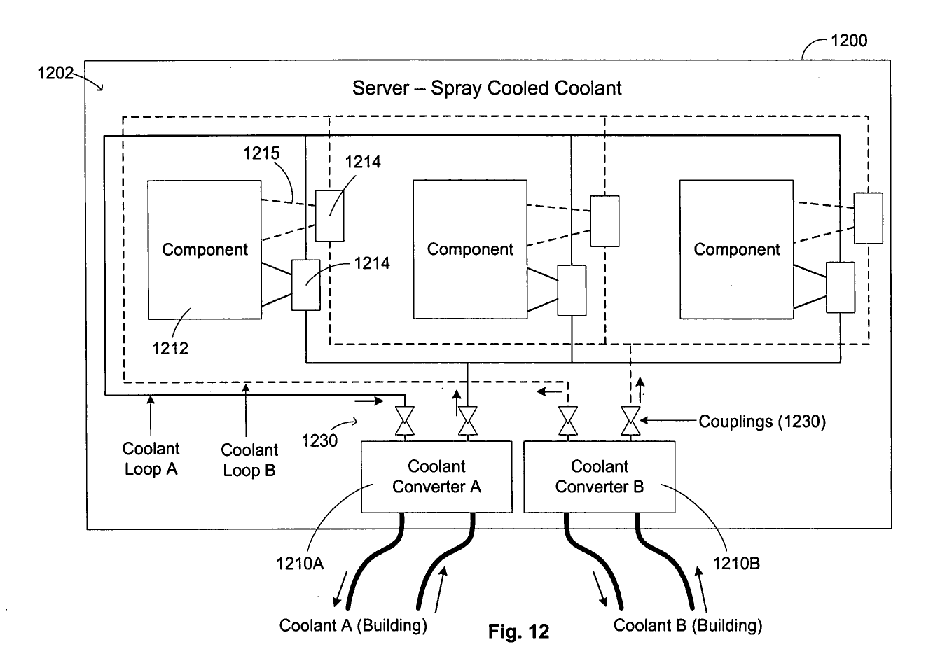

Any one or more of the embodiments in accordance with the present invention can be combined for yet additional embodiments. Further, other cooling techniques can be utilized with embodiments described herein to provide high performance cooling, such as, but not limited to, spray cooling and/or immersion cooling. FIG. 12 shows an exemplary embodiment of spray cooling for providing redundant cooling systems to electronic devices.

FIG. 12 shows a rack or server 1200 having an internal coolant system 1202 that supplies coolant with parallel loads. Two independent and separate coolant converters 1210A and 1210B connect to independent and separate coolant supply and return lines (shown as coolant A and coolant B). A plurality of heat generating components 1212 are cooled with spraying units 1214 along the internal coolant system 1202. This coolant system actually has two separate coolant loops (shown as coolant loop A and coolant loop B). As shown, coolant converter 1210A feeds or supplies coolant along coolant loop A, and coolant converter 1210B feeds or supplies coolant along coolant loop B. Each loop services the loads (i.e., heat generating components and spraying units) in a parallel fashion or network. A plurality of valves and/or couplings 1230 are used to connect and disconnect coolant loops or regulate operation between the two coolant loops.

Embodiments in accordance with the present invention enable components (example, coolant converters) to be hot swappable. Thus, a rack or server is not required to be turned off or shut down during servicing or repair. Further in some embodiments, couplings are designed to blindmate so that coolant converters simply slide in and slide out when making internal coolant connections (such as connections with a server). The coolant converters are also adapted to be modular and either internal or external to a server. Internal coolant converters require no additional floor space (i.e., in addition to the server or computer itself). Further, by providing dual building coolant supply as well as dual internal coolant loops, no single point of failure exists in the cooling systems.

The electronics or heat-generating components include any electronic component that generates heat during operation (such as, but not limited to, computers, servers, racks, data centers, etc.). For example, heat-generating components include, but are not limited to, one or more of electronic power circuits, integrated circuits (ICs) or chips, digital memory chips, application specific integrated circuits (ASICs), processors (such as a central processing unit (CPU) or digital signal processor (DSP)), discrete electronic devices (such as field effect transistors (FETs)), other types of transistors, resistors, capacitors, transistors, diodes, memories, and/or electronic devices that require heat to be thermally dissipated from the device for the device to operate properly or within a specified temperature range.

Further, although embodiments in accordance with the present invention are generally directed to liquid cooling systems, such systems can also use or combine airflow for cooling. For example, active heatsinks include one or more fans to assist in cooling.

Further as noted, the liquid cooling units or coolant converters can be modular and replaceable. In some embodiments, each unit or converter is an independently-operable unit or module that can be constructed with standardized units or dimensions for flexibility and replaceability for use in the electronic devices. As such, the units or converters can be connected to or removed from the electronic devices (example, a server) without connecting, removing, or replacing other components in the electronic device (example, the heat-generating components, other liquid cooling units, other coolant converters, heat exchangers, etc.). As such, the liquid cooling units or coolant converters can be serviced (example, replaced or repaired) without shutting down or turning off the respective electronic device (example, server housing the unit or converter).

As used herein, the term “module” means a unit, package, or functional assembly of electronic components for use with other electronic assemblies or electronic components. A module may be an independently-operable unit that is part of a total or larger electronic structure or device. Further, the module may be independently connectable and independently removable from the total or larger electronic structure (such as liquid cooling units or coolant converters being modules and connectable to servers in data centers).

While the invention has been disclosed with respect to a limited number of embodiments, those skilled in the art will appreciate, upon reading this disclosure, numerous modifications and variations. It is intended that the appended claims cover such modifications and variations and fall within the true spirit and scope of the invention.

What is claimed is:

1) A system, comprising:
a server; and
a liquid cooling unit connected to the server to provide fault-tolerant cooling to the server when a cooling system connected to the server fails.

2) The system of claim 1, wherein the liquid cooling unit is internal to the server and includes a storage device for storing extra coolant that is usable by the server when the cooling system connected to the server fails.

3) The system of claim 1, wherein the liquid cooling unit is external to the server and includes a storage device for storing extra coolant that is usable by the server when the cooling system connected to the server fails.

4) The system of claim 1, wherein the liquid cooling unit includes a pump for pumping fluid within the server, a heat exchanger for removing heat from the fluid, and a storage device for storing extra fluid.

5) The system of claim 1, wherein the liquid cooling unit includes a storage device having a porous mass inside a reservoir for providing additional cooling capacity for the server.

6) The system of claim 1, wherein the liquid cooling unit includes a storage device having a phase change material for providing additional cooling capacity for the server.

7) The system of claim 1, wherein the liquid cooling unit is internal to server and includes a phase change material that increases cooling capacity for coolant being supplied to heat generating components within the server when cooling to the server fails.

8) A server, comprising:
two coolant converters, wherein each coolant converter generates sufficient liquid cooling to cool heat generating components within the server.

9) The server of claim 8, wherein each coolant converter is powered from a different power supply.

10) The server of claim 8, wherein each coolant converter is connected to different and independent fluid supply and return lines.

11) The server of claim 8, wherein each coolant converter is internal to the server and includes a pump for pumping coolant through the server and control electronics for controlling flow rates of coolant circulated within the server.

12) The server of claim 8 further comprising:
a first power supply connected to one of the coolant converters; and
a second power supply connected to another of the coolant converters, wherein the first and second power supplies are located above the two coolant converters inside the server.

13) The server of claim 8, wherein each coolant converter is modular and provides redundant cooling to the server so the server does not overheat if one of the two coolant converters fails.

14) A datacenter, comprising:
at least one server; and
first and second liquid cooling units providing liquid coolant to the server, wherein if the first liquid cooling unit fails, the second liquid cooling unit sufficiently cools the server so the server does not overheat.

15) The datacenter of claim 14, wherein the first and second liquid cooling units are each connected to different supply and return lines within a building, the supply and return lines supplying the liquid coolant to the server.

16) The datacenter of claim 14, wherein the first and second liquid cooling units are located within the server.

17) The datacenter of claim 14, wherein the first and second liquid cooling units are modular and located within an electrical unit that is separate from the server.

18) The datacenter of claim 14, wherein the first and second liquid cooling units internally connect within the server with two separate coolant loops, each coolant loop connecting in parallel with heat loads within the server.

19) The datacenter of claim 14, wherein the first and second liquid cooling units internally connect within the server with two separate coolant loops, each coolant loop serially connecting with heat loads within the server.

20) The datacenter of claim 14, wherein the first and second liquid cooling units are modular, located within the server, and provide an airflow to aid in cooling heat generating components in the server.
